(19) United States
(12) Patent Application Publication
(10) Pub. No.: US 2024/0425754 A1
(43) Pub. Date: Dec. 26, 2024

(54) COMPOSITION FOR MANUFACTURING SEMICONDUCTOR, METHOD FOR TREATING OBJECT TO BE TREATED, AND METHOD FOR MANUFACTURING SEMICONDUCTOR ELEMENT

(71) Applicant: FUJIFILM Corporation, Tokyo (JP)

(72) Inventors: Yuta SHIGENOI, Haibara-gun (JP); Atsushi MIZUTANI, Haibara-gun (JP); Tomonori TAKAHASHI, Haibara-gun (JP)

(73) Assignee: FUJIFILM Corporation, Tokyo (JP)

(21) Appl. No.: 18/808,281

(22) Filed: Aug. 19, 2024

Related U.S. Application Data
(63) Continuation of application No. PCT/JP2023/005468, filed on Feb. 16, 2023.

(30) Foreign Application Priority Data
Feb. 22, 2022 (JP) 2022-025732

(51) Int. Cl. C09K 13/02; H01L 21/3213

(52) U.S. Cl. CPC C09K 13/02; H01L 21/32134

(57) ABSTRACT

An object of the present invention is to provide a composition for manufacturing a semiconductor, which is capable of selectively removing silicon in a case of being applied to an object to be treated containing silicon-germanium and silicon; a method for treating an object to be treated using the composition for manufacturing a semiconductor; and a method for manufacturing a semiconductor element using the composition for manufacturing a semiconductor.

The composition for manufacturing a semiconductor according to the present invention is a composition which includes a specific compound having two or more sulfur atoms and one or more heteroatoms other than a sulfur atom, an organic solvent, and water, and is alkaline.

### CROSS-REFERENCE TO RELATED APPLICATIONS

This application is a Continuation of PCT International Application No. PCT/JP2023/005468 filed on Feb. 16, 2023, which claims priority under 35 U.S.C. § 119(a) to Japanese Patent Application No. 2022-025732 filed on Feb. 22, 2022. The above applications are hereby expressly incorporated by reference, in their entirety, into the present application.

### BACKGROUND OF THE INVENTION

### 1. Field of the Invention

The present invention relates to a composition for manufacturing a semiconductor, a method for treating an object to be treated, and a method for manufacturing a semiconductor element.

### 2. Description of the Related Art

In a case of forming a circuit and an element, it is common to carry out an etching process using a chemical liquid. In this case, since a plurality of materials may be present on a substrate, it is desirable that the chemical liquid used for etching is a chemical liquid capable of selectively removing only a specific material.

For example, JP2019-050364A discloses an etchant suitable for selectively removing silicon with respect to silicon-germanium from a microelectronic device. More specifically, an etchant is disclosed that contains water, at least one of a quaternary ammonium compound or an amine compound, and a water-miscible solvent, and may contain at least one of a surfactant or a corrosion inhibitor.

### SUMMARY OF THE INVENTION

In recent years, with regard to a semiconductor treatment process of selectively etching silicon from an object to be treated containing silicon and silicon-germanium, there has been a demand for a composition for manufacturing a semiconductor having higher properties of selectively removing silicon with respect to silicon-germanium, and a method for treating an object to be treated.

The present inventors have conducted studies on the etchant (composition for manufacturing a semiconductor) described in JP2019-050364A, and have found that further improvement is required in properties of selectively removing silicon with respect to silicon-germanium.

Therefore, an object of the present invention is to provide a composition for manufacturing a semiconductor, which is capable of selectively removing silicon in a case of being applied to an object to be treated containing silicon-germanium and silicon.

In addition, another object of the present invention is to provide a method for treating an object to be treated using the composition for manufacturing a semiconductor and a method for manufacturing a semiconductor element using the composition for manufacturing a semiconductor.

As a result of extensive studies to achieve the foregoing objects, the present inventors have completed the present invention. That is, the present inventors have found that the foregoing objects can be achieved by the following configurations.

[1] A composition for manufacturing a semiconductor, comprising: a specific compound having two or more sulfur atoms and one or more heteroatoms other than a sulfur atom; an organic solvent; and water, in which the composition is alkaline.

[2] The composition for manufacturing a semiconductor according to [1], in which the specific compound has a disulfide group.

[3] The composition for manufacturing a semiconductor according to [1] or [2], in which the specific compound has at least one group selected from the group consisting of an amino group, a hydroxy group, a carbonyl group, and a carboxy group.

[4] The composition for manufacturing a semiconductor according to any one of [1] to [3], in which the specific compound has 3 or more hydroxy groups.

[5] The composition for manufacturing a semiconductor according to any one of [1] to [3], in which the specific compound has an aromatic hydrocarbon group substituted with a polar group containing a heteroatom other than a sulfur atom.

[6] The composition for manufacturing a semiconductor according to any one of [1] to [5], in which the composition for manufacturing a semiconductor further comprises a quaternary ammonium salt.

[7] The composition for manufacturing a semiconductor according to [6], in which the quaternary ammonium salt is a quaternary ammonium hydroxide.

[8] The composition for manufacturing a semiconductor according to any one of [1] to [7], in which the organic solvent has at least one of a hydroxy group or an amino group.

[9] The composition for manufacturing a semiconductor according to any one of [1] to [8], in which a content of the organic solvent is 40% by mass or more with respect to a total mass of the composition for manufacturing a semiconductor.

[10] The composition for manufacturing a semiconductor according to any one of [1]to [9], in which the composition is used for an object to be treated containing silicon-germanium and silicon.

[11] The composition for manufacturing a semiconductor according to any one of [1] to [10], in which a pH of the composition is 11 or more.

[12] A method for treating an object to be treated, comprising: bringing an object to be treated containing silicon-germanium and silicon into contact with the composition for manufacturing a semiconductor according to any one of [1] to [11] to remove silicon.

[13] A method for manufacturing a semiconductor element, comprising: a step of bringing an object to be treated containing silicon-germanium and silicon into contact with the composition for manufacturing a semiconductor according to any one of [1] to [11] to remove silicon.

According to the present invention, it is possible to provide a composition for manufacturing a semiconductor, which is capable of selectively removing silicon in a case of being applied to an object to be treated containing silicon-germanium and silicon.

In addition, according to the present invention, it is also possible to provide a method for treating an object to be treated and a method for manufacturing a semiconductor element.

### DESCRIPTION OF THE PREFERRED EMBODIMENTS

Hereinafter, the present invention will be described in more detail.

The description of the configuration requirements described below may be made based on the representative embodiments of the present invention, but the present invention is not limited to such embodiments.

Hereinafter, the meaning of each description in the present specification will be expressed.

In the present specification, the numerical range expressed using “to” means a range including the numerical values written before and after “to” as the lower limit value and the upper limit value, respectively.

In the present specification, “ppm” is an abbreviation for “parts per million” and means 10⁻⁶. In addition, “ppb” is an abbreviation for “parts per billion” and means 10⁻⁹. “ppt” is an abbreviation for “parts per trillion” and means 10⁻¹².

In the present specification, in a case where two or more types of a certain component are present, the “content” of the component means a total content of the two or more types of components.

In the present specification, “silicon” and “Si” refer to a material substantially composed of only a Si element. The “substantially” means that the content of the Si element is 90% by mass or more with respect to the total mass of the material. Therefore, other elements (excluding a Ge element) may be contained as long as the content of the Si element is within the above range.

In addition, in the present specification, “silicon-germanium” and “SiGe” refer to a material substantially composed of only a Si element and a Ge element. The “substantially” means that the total content of the Si element and the Ge element is 90% by mass or more with respect to the total mass of the material. Therefore, other elements may be contained as long as the total content of the Si element and the Ge element is within the above range. In addition, in the silicon-germanium, the content ratio of the Si element to the Ge element is not particularly limited, and the mass percentage of the content of the Ge element with respect to the total amount of the Si element and the Ge element is preferably 5% to 50% by mass.

Unless otherwise specified, the “exposure” includes exposure with a mercury lamp, a far ultraviolet ray represented by an excimer laser, an X-ray, or EUV light, and drawing with a corpuscular beam such as an electron beam or an ion beam.

The “preparation” includes not only providing a specific material by synthesis or formulation, but also procuring a predetermined item by purchase or the like.

A bonding direction of a divalent group (for example, —COO—) is not limited unless otherwise specified. For example, in a case where Y in a compound represented by “X—Y—Z” is —COO—, the compound may be any of “X—O—CO—Z” and “X—CO—O—Z”.

In the present specification, the “SP value” means a “value of a solubility parameter”, and the “solubility parameter” means a Hansen solubility parameter according to the equation explained in Hansen Solubility Parameters: A User's Handbook, Second Edition, C. M. Hansen (2007), Taylor and Francis Group, LLC (HSPiP Manual).

In the present specification, the “SP value” refers to a value obtained by calculating the SP value by Equation (S) using “Practical Hansen Solubility Parameters HSPiP, 5th Edition” (software version 5.1.03).

$${( SP value )}^{2} = {δ}_{d}^{2} + {δ}_{p}^{2} + {δ}_{h}^{2} \qquad Equation ( S )$$

In Equation (S), δ_{d} represents energy due to a dispersion force, δₚ represents energy due to a dipole-dipole interaction, and δₕ represents energy due to a hydrogen bond. The unit of the SP value is MPa^{1/2} (MPa^{0.5}).

In the present specification, unless otherwise specified, a weight-average molecular weight (Mw) and a number-average molecular weight (Mn) are each a value which is measured by a gel permeation chromatography (GPC) analysis apparatus with TSKgel GMHxL, TSKgel G4000HxL, or TSKgel G2000HxL (all trade names, manufactured by Tosoh Corporation) as a column, tetrahydrofuran (THF) as an eluent, a differential refractometer as a detector, and polystyrene as a standard substance, and converted in terms of the standard substance polystyrene.

In the present specification, unless otherwise specified, a “molecular weight” of a compound having a molecular weight distribution means the weight-average molecular weight (Mw).

In the present specification, a “low-molecular-weight compound” means a compound having a molecular weight of 1,000 or less, and a “high-molecular-weight compound” means a compound having a molecular weight of more than 1,000.

In the present specification, the performance of selectively removing (etching) Si in a case of being applied to an object to be treated containing SiGe and Si is also referred to as “Si selective removal properties”.

In addition, the performance of suppressing the removal (etching) of SiGe in a case of being applied to an object to be treated containing SiGe is also referred to as “SiGe anticorrosion properties”.

### <Composition for Manufacturing Semiconductor>

The composition for manufacturing a semiconductor according to an embodiment of the present invention (hereinafter, also referred to as “the present composition”) contains a specific compound having two or more sulfur atoms and one or more heteroatoms other than a sulfur atom, an organic solvent, and water, and is alkaline.

Although the mechanism by which, in a case of being applied to an object to be treated containing SiGe and Si, the present composition can selectively remove (etch) Si by having the above-mentioned configuration is not necessarily clear, the present inventors speculate that the specific compound contained in the present composition suppresses etching of SiGe, thereby making it possible to selectively etch Si.

Hereinafter, the components contained in the composition will be described in detail.

### [Specific Compound]

The composition contains a specific compound. The specific compound is a compound having two or more sulfur atoms and one or more heteroatoms other than a sulfur atom in a molecule.

The specific compound has two or more sulfur-containing groups containing one sulfur atom or has at least one sulfur-containing group containing two or more sulfur atoms.

Examples of the sulfur-containing group containing one sulfur atom include a thiol group, a thioether group (—S—), a sulfo group, a sulfonyl group, and a thioketone group (—SO—).

Examples of the sulfur-containing group containing two or more sulfur atoms include a polysulfide group such as a disulfide group (—S—S—).

The specific compound preferably has two or more thioether groups or a disulfide group, and more preferably a disulfide group.

In a case where the specific compound has a disulfide group, the substituent bonded to one sulfur atom of the disulfide group and the substituent bonded to the other sulfur atom of the disulfide group may be the same as or different from each other, and are preferably the same as each other.

The heteroatom other than a sulfur atom (hereinafter, also referred to as an “atom A”) contained in the specific compound is not particularly limited as long as it is an atom other than a sulfur atom, a carbon atom, and a hydrogen atom, and examples thereof include an oxygen atom, a nitrogen atom, and a halogen atom such as a fluorine atom, a chlorine atom, a bromine atom, or an iodine atom.

Examples of the specific compound include a compound having an organic group containing the atom A, in addition to the sulfur-containing group. Examples of the organic group containing the atom A include a hydrocarbon group having a polar group containing the atom A and a heterocyclic group containing the atom A.

Examples of the polar group containing the atom A (hereinafter, also referred to as a “polar group A”) include a hydroxy group, an ether group, a carbonyl group, a carboxy group, an amino group, an amide group, an imide group, and a cyano group.

Note that the amino group is a generic term for a primary amino group (—NH₂), a secondary amino group (—NH—), and a tertiary amino group (—N<), and may be any of a primary to tertiary amino groups. The amino group contained in the specific compound is preferably a primary amino group. In addition, the hydroxy group as the polar group A does not include —OH contained in the carboxy group, and the carbonyl group as the polar group A does not include —CO— contained in the carboxy group.

The polar group A is preferably at least one group selected from the group consisting of an amino group, a hydroxy group, a carbonyl group, and a carboxy group, and more preferably at least one group selected from the group consisting of an amino group, a hydroxy group, and a carboxy group.

The polar group A may form a salt with a counter ion. Examples of the salt include a hydrochloride, a sulfate, and a sodium salt.

Examples of the hydrocarbon group having the polar group A include an aliphatic hydrocarbon group substituted with the polar group A, an aromatic hydrocarbon group substituted with the polar group A, and a hydrocarbon group in which a group consisting of a combination of an aliphatic hydrocarbon group and an aromatic hydrocarbon group is substituted with the polar group A.

The aliphatic hydrocarbon group may be linear, branched, or cyclic, and is preferably linear. The aliphatic hydrocarbon group may be saturated or unsaturated, and is preferably an alkyl group. The number of carbon atoms in the aliphatic hydrocarbon group is preferably 1 to 6 and more preferably 1 to 4.

Examples of the aromatic hydrocarbon group include a phenyl group and a naphthalenyl group, among which a phenyl group is preferable.

The number of the polar groups A contained in the hydrocarbon group is not particularly limited as long as it is 1 or more, and is preferably 1 to 3 and more preferably 1 or 2.

The heterocyclic group containing the atom A (hereinafter, also referred to as a “heterocyclic group A”) may be monocyclic or polycyclic, and may be aromatic or non-aromatic. The number of ring members of the heterocyclic group A is not particularly limited, and is, for example, 5 to 7, preferably 5 or 6, and more preferably 6. Examples of the heterocyclic group A include a pyrrolidinyl group, a piperidinyl group, a tetrahydrofuranyl group, a tetrahydropyranyl group, a morpholino group, a pyridinyl group, a pyrazinyl group, and a furanyl group.

The total number of the polar group A and the heterocyclic group A contained in the specific compound is preferably 2 or more, more preferably 2 to 6, and still more preferably 2 to 4.

In a case where the specific compound has a hydroxy group as the polar group A, it is preferable that the specific compound has three or more hydroxy groups from the viewpoint of more excellent Si selective removal properties. The number of hydroxy groups in this case is, for example, 6 or less, and preferably 4 or less.

The organic group containing the atom A, which is contained in the specific compound, is preferably an aliphatic hydrocarbon group containing 1 to 6 carbon atoms and having at least one group selected from the group consisting of an amino group, a hydroxy group, a carbonyl group, and a carboxy group, an aromatic hydrocarbon group having at least one group selected from the group consisting of an amino group, a hydroxy group, a carbonyl group, and a carboxy group, or a heterocyclic group containing the atom A and having 5 or 6 ring members; and more preferably an alkyl group containing 1 to 4 carbon atoms substituted with at least one group selected from the group consisting of an amino group, a hydroxy group, and a carboxy group, a phenyl group having a carboxy group, or a morpholino group.

The specific compound may be a low-molecular-weight compound or a high-molecular-weight compound (a polymer), and is preferably a low-molecular-weight compound. The molecular weight of the specific compound is preferably 100 to 1,000 and more preferably 150 to 500.

The specific compound is preferably a compound represented by Formula (1).

X₁—S-L-S—X₂ (1)

In Formula (1), X₁ and X₂ each independently represent an organic group containing the atom A, and L represents a single bond or a divalent linking group.

The organic group containing the atom A, represented by each of X₁ and X₂, is the same as the above-mentioned organic group containing the atom A, including preferred aspects thereof. X₁ and X₂ may be the same as or different from each other, and are preferably the same as each other.

Examples of the divalent linking group represented by L include a divalent hydrocarbon group, among which an alkylene group is preferable. The number of carbon atoms in the hydrocarbon group or the alkylene group is preferably 1 to 6 and more preferably 1 to 4. More specific examples of the alkylene group include a methylene group, an ethylene group, a 1,2-propylene group, and a 1,3-propylene group.

L is preferably a single bond or an alkylene group containing 1 to 4 carbon atoms, more preferably a single bond or an ethylene group, and still more preferably a single bond.

That is, the specific compound is more preferably a compound represented by Formula (2).

X₁—S—S—X₂ (2)
X₁ and X₂ in Formula (2) are the same as X₁ and X₂ in Formula (1), including preferred aspects thereof.

Hereinafter, specific examples of the specific compound will be shown. However, the specific compound is not limited to these compounds.

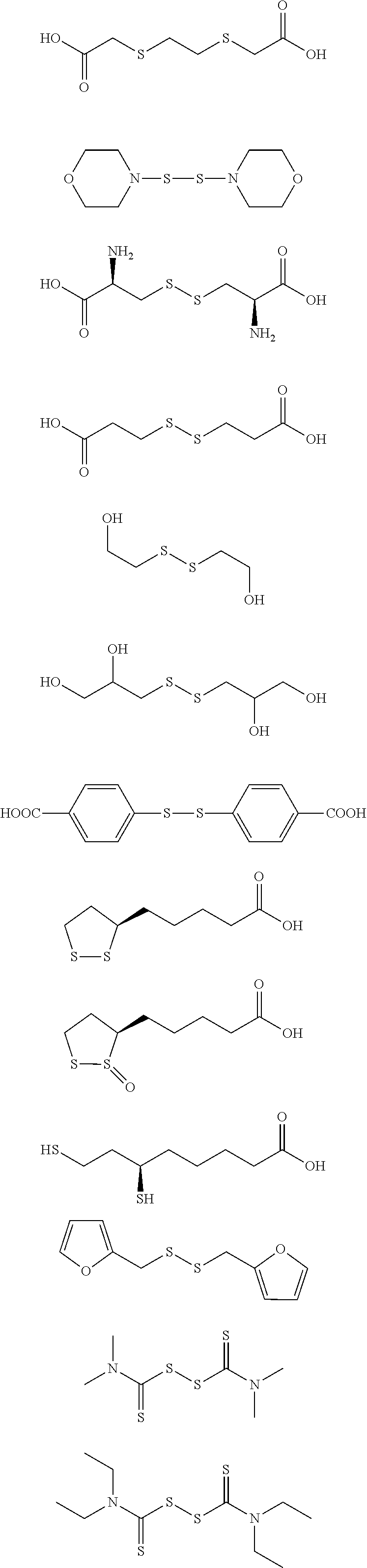

The specific compounds may be used alone or in combination of two or more kinds thereof.

The content of the specific compound is not particularly limited, and is, for example, 0.001% to 20.0% by mass with respect to the total mass of the composition. From the viewpoint of more excellent Si selective removal properties, the content of the specific compound is preferably 10.0% by mass or less, more preferably 5.0% by mass or less, and still more preferably 2.0% by mass with respect to the total mass of the composition. In addition, from the viewpoint of more excellent SiGe anticorrosion properties, the content of the specific compound is preferably 0.01% by mass or more and more preferably 0.1% by mass or more.

### [Organic Solvent]

The present composition contains an organic solvent.

The organic solvent is an organic compound that is liquid at 25° C. In this regard, the specific compound is not included in the organic solvent.

Examples of the organic solvent include an alcohol-based solvent, an amide-based solvent, and a sulfur-containing solvent other than the specific compound.

Examples of the alcohol-based solvent include a polyol, an alkoxyalcohol, a saturated aliphatic monohydric alcohol, an unsaturated non-aromatic monohydric alcohol, an alcohol containing a ring structure, an alcohol having an amino group (aminoalcohol), and a glycol ether.

The number of carbon atoms in the alcohol-based solvent is preferably 1 to 10 and more preferably 1 to 6.

Examples of the polyol include ethylene glycol, quaternary ammonium salt represented by Formula (a), propylene glycol, 2-methyl-1,3-propanediol, 1,3-propanediol, 2,2-dimethyl-1,3-propanediol, 1,4-butanediol, 1,3-butanediol, 1,2-butanediol, 2,3-butanediol, 2-methylpentane-2,4-diol, glycerol (glycerin), dipropylene glycol, and triethylene glycol.

Examples of the saturated aliphatic monohydric alcohol include methanol and ethanol.

Examples of the unsaturated non-aromatic monohydric alcohol include propargyl alcohol.

Examples of the alcohol containing a ring structure include 1,3-cyclopentanediol.

Examples of the amino group contained in the aminoalcohol include —NH₂, —NHR, and —NRR′. R and R′ each represent a substituent. R and R′ may be the same as or different from each other. Examples of the aminoalcohol include methanolamine, monoethanolamine, diethanolamine, and 1-amino-2-propanol.

Examples of the amide-based solvent include formamide, N-methylformamide, acetamide, and N-methylacetamide.

The number of carbon atoms in the amide-based solvent is preferably 1 to 4.

Examples of the sulfur-containing solvent include dimethyl sulfone, dimethyl sulfoxide (DMSO), and sulfolane.

The number of carbon atoms in the sulfur-containing solvent is preferably 1 to 4.

From the viewpoint of more excellent Si selective removal properties, the organic solvent is preferably an organic solvent having at least one of a hydroxy group or an amino group.

Examples of the organic solvent having a hydroxy group include the above-mentioned alcohol-based solvent, and examples of the organic solvent having an amino group include the above-mentioned aminoalcohol and the above-mentioned amide-based solvent.

Above all, an organic solvent having two or more groups selected from the group consisting of a hydroxy group and an amino group is more preferable. Examples of the organic solvent having two or more groups selected from the group consisting of a hydroxy group and an amino group include the above-mentioned polyol and the above-mentioned aminoalcohol.

From the viewpoint of more excellent SiGe anticorrosion properties, the SP value of the organic solvent is preferably 10 to 50 MPa^{1/2}, more preferably 15 to 45 MPa^{1/2}, and still more preferably 20 to 40 MPa^{1/2} The method for measuring the SP value of the organic solvent is as described above.

The organic solvents may be used alone or in combination of two or more kinds thereof.

The content of the organic solvent is not particularly limited. From the viewpoint of excellent SiGe anticorrosion properties, the content of the organic solvent is preferably 10% by mass or more, more preferably 25% by mass or more, and still more preferably 40% by mass or more with respect to the total mass of the composition. In addition, the content of the organic solvent is preferably 90% by mass or less, more preferably 80% by mass or less, and still more preferably 70% by mass or less with respect to the total mass of the composition.

The ratio of the content of the organic solvent to the content of the specific compound is not particularly limited, and is preferably 1 to 10,000, more preferably 5 to 5,000, still more preferably 10 to 1,000, and particularly preferably 20 to 1,000, from the viewpoint that Si selective removal properties and SiGe anticorrosion properties are more excellent.

### [Water]

The present composition contains water.

The water is preferably water that has been subjected to a purification treatment, such as distilled water, ion exchange water, and ultrapure water, and more preferably ultrapure water used for manufacturing semiconductors. The water contained in the composition may contain a tiny amount of components that are unavoidably mixed in.

The content of water is not particularly limited. From the viewpoint that Si selective removal properties and SiGe anticorrosion properties are more excellent, the content of water is preferably 5% to 95% by mass, more preferably 20% to 80% by mass, and still more preferably 30% to 60% by mass with respect to the total mass of the composition.

In addition, the ratio of the content of water to the content of the organic solvent is not particularly limited. From the viewpoint that Si selective removal properties and SiGe anticorrosion properties are more excellent, the ratio of the content of water to the content of the organic solvent is preferably 0.1 to 10, more preferably 0.2 to 3.0, and still more preferably 0.5 to 1.0.

### [Optional Components]

The composition may contain optional components in addition to the components described above.

Hereinafter, the optional components that may be contained in the composition will be described in detail.

### (Quaternary Ammonium Salt)

The composition may contain a quaternary ammonium salt, and from the viewpoint that Si selective removal properties are more excellent, it is preferable that the composition contains a quaternary ammonium salt.

The quaternary ammonium salt is a compound composed of a quaternary ammonium cation in which a nitrogen atom is substituted with four hydrocarbon groups, and an anion. Examples of the quaternary ammonium salt include quaternary ammonium hydroxide, quaternary ammonium fluoride, quaternary ammonium chloride, quaternary ammonium bromide, quaternary ammonium iodide, and quaternary ammonium acetate.

Among these, quaternary ammonium hydroxide, quaternary ammonium fluoride, quaternary ammonium chloride, or quaternary ammonium bromide is preferable, quaternary ammonium hydroxide or quaternary ammonium fluoride is more preferable, and quaternary ammonium hydroxide is still more preferable.

The quaternary ammonium salt is preferably represented by Formula (a).

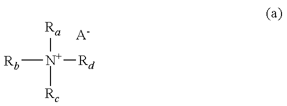

In Formula (a), Rₐ to R_{d} each independently represent an alkyl group which may have a substituent. In addition, two groups selected from Rₐ to R_{d} may be bonded to each other to form a ring.

In Formula (a), A⁻ represents a monovalent anion.

The alkyl group represented by each of Rₐ to R_{d} may be linear or branched, and is preferably linear. The number of carbon atoms in the alkyl group moiety of the alkyl group is preferably 1 to 20, more preferably 1 to 8, and still more preferably 1 to 4.

In addition, the methylene group constituting the alkyl group may be substituted with a divalent substituent such as —O—.

Specific examples of the alkyl group include a methyl group, an ethyl group, a propyl group, a butyl group, a pentyl group, a hexyl group, a heptyl group, an octyl group, a nonyl group, a decyl group, an undecyl group, a dodecyl group, a tridecyl group, a tetradecyl group, a pentadecyl group, and a hexadecyl group, among which a methyl group, an ethyl group, a propyl group, or a butyl group is preferable, and a methyl group is more preferable.

Examples of the substituent which may be contained in the alkyl group represented by each of Rₐ to R_{d} include a hydroxy group and a phenyl group. Examples of the alkyl group having a substituent include a 2-hydroxyethyl group, a 2-hydroxypropyl group, and a benzyl group.

The ring formed by bonding two groups selected from Rₐ to R_{d} with each other may be an alicyclic ring or an aromatic ring, and is preferably an alicyclic ring.

The total number of carbon atoms of Rₐ to R_{d} contained in the quaternary ammonium salt represented by Formula (a) is not particularly limited, and is preferably 4 to 20 and more preferably 4 to 14.

In Formula (a), examples of the monovalent anion represented by A⁻ include OH⁻, F⁻, Cl⁻, Br, I⁻, NO₃⁻, CH₃COO⁻, and CH₃CH₂SO₄, among which OH⁻, F⁻, Cl⁻, or Br is preferable, OH⁻ or F⁻ is more preferable, and OH⁻ is still more preferable.

Examples of the quaternary ammonium salt represented by Formula (a) include a tetramethylammonium salt, a tetraethylammonium salt, a tetrabutylammonium salt, an ethyltrimethylammonium salt, a triethylmethylammonium salt, a diethyldimethylammonium salt, a tributylmethylammonium salt, a dimethyldipropylammonium salt, a dodecyltrimethylammonium salt, a trimethyltetradecylammonium salt, a hexadecyltrimethylammonium salt, a benzyltrimethylammonium salt, a benzyltriethylammonium salt, a (2-hydroxyethyl)trimethylammonium salt (also referred to as “choline”), a triethyl(2-hydroxyethyl)ammonium salt, a diethylbis(2-hydroxyethyl)ammonium salt, an ethyltris(2-hydroxyethyl)ammonium salt, and a tris(2-hydroxyethyl)methylammonium salt.

Above all, it is preferable to contain at least one selected from the group consisting of a tetramethylammonium salt, a tetraethylammonium salt, a tetrabutylammonium salt, an ethyltrimethylammonium salt, a triethylmethylammonium salt, a diethyldimethylammonium salt, a tributylmethylammonium salt, and a dimethyldipropylammonium salt.

These quaternary ammonium salts more preferably have the above-mentioned preferred monovalent anion.

The molecular weight of the quaternary ammonium salt is preferably 90 to 1000, more preferably 90 to 500, and still more preferably 90 to 300.

The quaternary ammonium salts may be used alone or in combination of two or more kinds thereof.

The content of the quaternary ammonium salt is preferably 0.01% to 15.0% by mass, more preferably 0.1% to 10.0% by mass, and still more preferably 0.5% to 6.0% by mass with respect to the total mass of the composition.

From the viewpoint that Si selective removal properties and SiGe anticorrosion properties are more excellent, a mass ratio of the content of the quaternary ammonium salt to the content of the specific compound is preferably 0.1 to 1,000, more preferably 0.5 to 100, and still more preferably 1.0 to 50.

### (Basic Compound)

The composition may contain a basic compound. The basic compound is a compound that is alkaline (having a pH of more than 7.0) in an aqueous solution at 25° C. In this regard, the basic compound does not include the above-mentioned quaternary ammonium salt and organic solvent.

Examples of the basic compound include an organic base, an inorganic base, and salts thereof, other than the above-mentioned quaternary ammonium compound.

Examples of the organic base include an alkylamine compound or a salt thereof, an amine oxide compound, a nitro compound, a nitroso compound, an oxime compound, a ketoxime compound, an aldoxime compound, a lactam compound, and an isocyanide compound, among which an alkylamine compound or a salt thereof is preferable.

The alkyl group moiety of the alkylamine compound may have a substituent. The substituent is not particularly limited, and examples thereof include a hydroxy group and a phenyl group. The methylene group constituting the alkyl group moiety may be substituted with a divalent linking group such as —O—. The alkyl group moieties may be bonded to each other to form a ring.

The alkylamine compound may form a salt with an acid.

Examples of the alkylamine compound include methylamine, ethylamine, dimethylamine, diethylamine, trimethylamine, triethylamine, N-methyldiethanolamine, N-ethyldiethanolamine, N,N-dimethylethanolamine, N-methylmorpholine, N-ethylmorpholine, and salts thereof.

Examples of the inorganic base include alkali metal hydroxides such as sodium hydroxide and potassium hydroxide, alkaline earth metal hydroxides, and ammonia or a salt thereof.

The content of the basic compound is not particularly limited. In a case where the composition contains a basic compound, the content of the basic compound is preferably 0.01% to 20% by mass with respect to the total mass of the composition.

It is also preferable that the content of the basic compound is adjusted such that the pH of the composition is in a suitable range which will be described later.

(Acidic compound)

The composition may contain an acidic compound. The acidic compound is a compound that is acidic (having a pH of less than 7.0) in an aqueous solution at 25° C. In this regard, the acidic compound does not include the specific compound.

Examples of the acidic compound include an inorganic acid, an organic acid, and salts thereof. Examples of the inorganic acid include sulfuric acid, hydrochloric acid, phosphoric acid, nitric acid, hydrofluoric acid, perchloric acid, hypochlorous acid, and salts thereof. Examples of organic acid include carboxylic acid, sulfonic acid, and salts thereof.

In a case where the composition contains an acidic compound, a content of the acidic compound may be, for example, 0.001% to 20% by mass with respect to the total mass of the composition. It is preferable that the composition does not contain an acidic compound.

In addition, it is also preferable that the content of the acidic compound is adjusted such that the pH of the composition is in a suitable range which will be described later.

### (Surfactant)

The composition may contain a surfactant.

The surfactant is not particularly limited as long as it is a compound having a hydrophilic group and a hydrophobic group (lipophilic group) in one molecule. Examples of the surfactant include an anionic surfactant, a cationic surfactant, and a nonionic surfactant.

Examples of the hydrophobic group contained in the surfactant include an aliphatic hydrocarbon group, an aromatic hydrocarbon group, and a combination thereof.

In a case where the hydrophobic group includes an aromatic hydrocarbon group, the number of carbon atoms in the hydrophobic group is preferably 6 or more and more preferably 10 or more.

In a case where the hydrophobic group does not include an aromatic hydrocarbon group and is composed only of an aliphatic hydrocarbon group, the number of carbon atoms in the hydrophobic group is preferably 8 or more and more preferably 10 or more. The upper limit of the number of carbon atoms in the hydrophobic group is not particularly limited, and is preferably 24 or less and more preferably 20 or less.

Nonionic surfactants having a hydrophilic-lipophilic balance (HLB) value of 12.0 to 15.0, which are described in paragraph [0029] and subsequent paragraphs of JP2021-009885A, are also preferable as the surfactant. The HLB value of the nonionic surfactant is preferably 12.5 to 14.0 and more preferably 12.5 to 13.5.

The HLB value is a value representing a degree of affinity of a surfactant for water and a water-insoluble organic compound. Typically, the HLB value is defined by Expression (G).

Expression G: HLB value=20×formula weight of hydrophilic part of surfactant/molecular weight of surfactant

Expression (G) can be defined in the nonionic surfactant.

Specific examples of the surfactant include polyoxyalkylene alkyl ether, polyoxyalkylene alkyl phenyl ether, polyoxyethylene fatty acid ester, polyoxyethylene sorbitan fatty acid ester, polyoxyethylene sorbitol fatty acid ester, glycerin fatty acid ester, and triethanolamine oleate.

In a case where the composition contains a surfactant, the content of the surfactant is not particularly limited, and is preferably 10 ppm by mass or more and more preferably 30 ppm by mass or more with respect to the total mass of the composition. The upper limit of the content of the surfactant is not particularly limited, and is preferably 10% by mass or less and more preferably 5% by mass or less with respect to the total mass of the composition, from the viewpoint of suppressing foaming of the composition.

### (Anticorrosive)

The composition may contain an anticorrosive.

The anticorrosive is added to the composition for the purpose of preventing etching of other materials present on an object to be treated, which will be described later. In this regard, the anticorrosive does not include the above-mentioned organic solvent.

The type of the anticorrosive is appropriately selected depending on the material type of other materials present on the object to be treated.

Examples of the anticorrosive include an amine compound, an imine compound, a thiol compound, and a thioether compound. Above all, an imine compound is preferable and an unsaturated heterocyclic compound containing nitrogen is more preferable.

Examples of the unsaturated heterocyclic compound containing nitrogen include pyridine, triazine, imidazole, benzimidazole, purine, xanthine, and derivatives thereof.

In a case where the composition contains an anticorrosive, the content of the anticorrosive is not particularly limited, and is preferably 0.1% by mass or more and more preferably 1% by mass or more with respect to the total mass of the composition. The upper limit of the content of the anticorrosive is not particularly limited, and is preferably 10% by mass or less and more preferably 5% by mass or less with respect to the total mass of the composition.

### <Properties of Composition for Manufacturing Semiconductor>

Hereinafter, the chemical properties and physical properties exhibited by the composition will be described.

[pH]

The pH of the composition is not particularly limited, and is preferably 9.0 or more, more preferably 11.0 or more, and still more preferably 13.0 or more from the viewpoint that Si selective removal properties are more excellent. The upper limit of the pH of the composition is not particularly limited, and is preferably 15.0 or less.

In the present specification, the pH of the composition is a value obtained by measuring pH at 25° C. using a pH meter (F-71S (trade name), manufactured by Horiba, Ltd.).

### [Coarse Particles]

It is preferable that the composition is substantially free of coarse particles.

The “coarse particles” mean particles having a diameter of 0.2 m or more in a case where the shape of the particles is regarded as a sphere. In addition, the phrase “substantially free of coarse particles” means that the number of particles having a diameter of 0.2 m or more in 1 mL of the composition is 10 or less in a case where the composition is measured using a commercially available measuring device in a light scattering liquid-borne particle measuring method. The lower limit of the number of coarse particles in the composition is preferably 0 or more.

The coarse particles contained in the composition are, for example, particles such as dust, dirt, organic solids, and inorganic solids contained as impurities in raw materials, and particles such as dust, dirt, organic solids, and inorganic solids brought in as contaminants during the preparation of the composition, which are ultimately present as particles without being dissolved in the composition.

The method of measuring the content of the coarse particles may be, for example, a method of measuring the content of the coarse particles in a liquid phase using a commercially available measuring device in a light scattering liquid-borne particle measuring method using a laser as a light source.

The method of removing the coarse particles may be, for example, a filtering treatment.

### <Method for Manufacturing Composition for Manufacturing Semiconductor>

For example, a known manufacturing method can be used as the method for manufacturing the composition.

The method for manufacturing the composition may include one or more steps selected from the group of steps consisting of a composition preparation step, a filtration step, and a static neutralization step.

Hereinafter, the steps that can be included in the manufacturing step of the composition will be described in detail. In addition, a container for accommodating the composition will also be described in detail.

It is preferable that each of the steps in the method for manufacturing the composition is carried out in a clean room.

The clean room preferably satisfies the 14644-1 clean room standards. In addition, the clean room preferably satisfies any of International Organization for Standardization (ISO) class 1, ISO class 2, ISO class 3, or ISO class 4, more preferably ISO class 1 or ISO class 2, and still more preferably ISO class 1.

### [Composition Preparation Step]

Examples of the composition preparation step include a method of preparing each component of a specific compound, an organic solvent, water, and an optional component, and then mixing the components to prepare a composition. In the composition preparation step, the order in which the components are mixed is not particularly limited.

In addition, the composition may be manufactured by manufacturing a concentrated solution having a lower content of one or more solvents selected from the group consisting of an organic solvent and water than in a case of being used, and diluting the concentrated solution with a diluent (an organic solvent or water, or both an organic solvent and water) at the time of being used to adjust the content of each component to a desired content. The composition may also be manufactured by diluting a concentrated solution with a diluent and then adjusting the pH of the concentrated solution to a set pH using a basic compound or an acidic compound. In a case of diluting the concentrated solution, a predetermined amount of the diluent may be added to the concentrated solution or a predetermined amount of the concentrated solution may be added to the diluent.

### (Filtration Step)

In order to remove foreign matters, coarse particles, and the like from the composition, the method for manufacturing the composition may include a filtration step of filtering the composition.

Examples of the filtering method include a known filtration method, among which filtering using a filter is preferable.

Examples of the filter used for filtering include filters used for known filtering.

Examples of materials constituting the filter include a fluororesin such as polytetrafluoroethylene (PTFE), a polyamide resin such as nylon, and a polyolefin resin (including a high density polyolefin resin and an ultra high molecular weight polyolefin resin) such as polyethylene or polypropylene (PP), among which a polyamide resin, PTFE, or polypropylene (including high density polypropylene) is preferable.

Using a filter composed of the above-mentioned material makes it possible to more effectively remove foreign matters having high polarity, which are likely to cause defects, from the composition.

The critical surface tension of the filter is preferably 70 mN/m or more. The upper limit of the critical surface tension of the filter is preferably 95 mN/m or less. Above all, the critical surface tension of the filter is more preferably 75 to 85 mN/m.

The value of the critical surface tension is a nominal value of a manufacturer.

Using a filter having a critical surface tension in the above range makes it possible to more effectively remove foreign matters having high polarity, which are likely to cause defects, from the composition.

The pore diameter of the filter is preferably 0.001 to 1.0 m, more preferably 0.02 to 0.5 m, and still more preferably 0.01 to 0.1 km. In a case where the pore diameter of the filter is within the above range, fine foreign matters can be removed from the composition while suppressing filter clogging.

The filter may be a combination of two or more types of filters.

The filtering using a first filter may be carried out once or twice or more.

In a case where filtering is carried out twice or more by combining a first filter and a second filter different from the first filter, the first filter and the second filter may be the same as or different from each other, and the first filter and the second filter are preferably different from each other. It is preferable that the first filter and the second filter differ from each other in at least one of the pore diameter or the constituent material.

It is preferable that the filter pore diameter in the second and subsequent filterings is the same as or smaller than the filter pore diameter in the first filtering. In addition, within the above range of the pore diameters of the filters, first filters having different pore diameters may be combined. With regard to the pore diameters of the filter, reference can be made to nominal values of filter manufacturers.

Examples of the filter include filters manufactured by Nihon Pall Ltd., Advantec Toyo Roshi Kaisha, Ltd., Entegris Japan Co., Ltd., and Kitz Micro Filter Corporation.

Specific examples of the filter include P-NYLON FILTER made of polyamide (pore diameter: 0.02 m, critical surface tension: 77 mN/m, manufactured by Nihon Pall Ltd.), PE CLEAN FILTER made of high density polyethylene (pore diameter: 0.02 m, manufactured by Nihon Pall Ltd.), and PE CLEAN FILTER made of high density polyethylene (pore diameter: 0.01 μm, manufactured by Nihon Pall Ltd.).

Examples of the second filter include a filter formed of the same material as that of the first filter.

The pore diameter of the second filter may be the same as the pore diameter of the first filter.

In a case where the pore diameter of the second filter is smaller than the pore diameter of the first filter, the ratio of the pore diameter of the second filter to the pore diameter of the first filter (pore diameter of second filter/pore diameter of first filter) is preferably 0.01 to 0.99, more preferably 0.1 to 0.9, and still more preferably 0.3 to 0.9. In a case where the pore diameter of the second filter is within the above range, fine foreign matters mixed in the composition can be further removed.

For example, filtering may be carried out in such a manner that filtering using the first filter is carried out with a mixed liquid containing a part of components of a composition, and after mixing the remaining components with the mixed liquid to prepare the composition, filtering using the second filter is carried out.

The filter to be used is preferably subjected to a washing treatment prior to filtering the composition.

The washing treatment is preferably a washing treatment using a liquid, and more preferably a washing treatment using a liquid containing a composition and components contained in the composition.

The temperature of the composition during filtering is preferably room temperature (25° C.) or lower, more preferably 23° C. or lower, and still more preferably 20° C. or lower. The lower limit of the temperature of the composition during filtering is preferably 0° C. or higher, more preferably 5° C. or higher, and still more preferably 10° C. or higher.

In a case where the temperature of the composition during filtering is within the above temperature range, the amounts of particulate foreign matters and impurities contained in the composition are reduced, so that the filtering can be carried out more efficiently.

(Static neutralization step)

The method for manufacturing a composition may further include a static neutralization step of statically neutralizing the composition.

### [Container]

For example, a known container can be used as the container for accommodating the composition.

The container is preferably a container for semiconductor applications which has a high degree of internal cleanliness and has a low elution of impurities.

Examples of the container include “CLEAN BOTTLE” series (manufactured by Aicello Chemical Co., Ltd.) and “PURE BOTTLE” (manufactured by Kodama Plastics Co., Ltd.). In addition, from the viewpoint of preventing the incorporation of impurities (contamination) into the raw materials and the composition, it is also preferable to use a multi-layer container in which an interior wall of the container has a six-layer structure consisting of six types of resins, or a multi-layer container in which an interior wall of the container has a seven-layer structure consisting of seven types of resins.

Examples of the multi-layer container include the containers described in JP2015-123351A, the contents of which are incorporated herein by reference.

Examples of the material for the interior wall of the container include a first resin of at least one selected from the group consisting of a polyethylene resin, a polypropylene resin, and a polyethylene-polypropylene resin, a second resin different from the first resin, and a metal such as stainless steel, Hastelloy, Inconel, or Monel. In addition, it is preferable that the interior wall of the container is formed of or coated with the above-mentioned materials.

The second resin is preferably a fluororesin (perfluororesin).

In a case where a fluororesin is used, elution of an oligomer of ethylene or propylene can be suppressed.

Examples of the container include a FluoroPure PFA composite drum (manufactured by Entegris, Inc.), and the containers described on page 4 of JP1991-502677A (JP-H03-502677A), page 3 of WO2004/016526A, and pages 9 and 16 of WO99/046309A.

In addition to the fluororesin, for example, quartz and an electropolished metal material (a metal material subjected to electropolishing) are also preferable for the interior wall of the container.

The metal material used for the electropolished metal material is preferably a metal material containing at least one selected from the group consisting of chromium (Cr) and nickel (Ni), in which the total content of Cr and Ni is more than 25% by mass (more preferably 30% to 90% by mass) with respect to the total mass of the metal material.

Examples of such a metal material include stainless steel and a Ni—Cr alloy. Examples of the stainless steel include a known stainless steel, among which a stainless steel containing 8% by mass or more of Ni is preferable, and an austenitic stainless steel containing 8% by mass or more of Ni is more preferable. Examples of the Ni—Cr alloy include a known Ni—Cr alloy, among which a Ni—Cr alloy having a Ni content of 40% to 75% by mass and a Cr content of 1% to 30% by mass is preferable. The Ni—Cr alloy may further contain boron, silicon, tungsten, molybdenum, copper, or cobalt in addition to Ni and Cr, if necessary.

Examples of the method for electropolishing a metal material include known methods such as the methods described in paragraphs [0011] to [0014] of JP2015-227501A, the contents of which are incorporated herein by reference and paragraphs [0036] to [0042] of JP2008-264929A, the contents of which are incorporated herein by reference.

The metal material is preferably subjected to buffing. Examples of the method of buffing include a known method. The size of abrasive grains used for finishing the buffing is preferably #400 or less from the viewpoint that surface asperities of the metal material are likely to be further reduced. The buffing is preferably carried out before the electropolishing.

The metal material may be a material that has been subjected to one of multi-stage buffing that is carried out by changing the size or the like of the abrasive grains, acid washing, magnetorheological finishing, and the like, or a combination of two or more treatments selected from the above.

It is preferable to wash the inside of the container before being filled with the composition.

The liquid used for washing can be appropriately selected depending on the intended use, and is preferably a liquid containing a composition or at least one of the components added to the composition.

The inside of the container may be purged with an inert gas (for example, nitrogen or argon) having a purity of 99.99995% by volume or higher from the viewpoint of preventing changes in the components of the composition during storage. In particular, a gas having a low moisture content is preferable. In addition, transportation and storage of the container accommodating the composition may be carried out either at normal temperature or under temperature control. Above all, from the viewpoint of preventing deterioration, it is preferable to control the temperature in a range of −20° C. to 20° C.

### <Use of Composition for Manufacturing Semiconductor>

The present composition is a composition for manufacturing a semiconductor. In the present specification, the phrase “for manufacturing a semiconductor” means that the composition is used for manufacturing a semiconductor element.

The composition can also be used in a step for manufacturing a semiconductor element and can be used for treating, for example, a material composed of silicon, an insulating film, a resist film, an anti-reflection film, an etching residue, and an ashing residue, which are present on a substrate. The composition may be used for treating a substrate after chemical mechanical polishing.

In particular, the composition is preferably used for treating an object to be treated containing SiGe and Si (hereinafter, also simply referred to as “object to be treated”). The element obtained by treating the object to be treated with the composition may be, for example, preferably a field effect transistor (FET) and more preferably a gate-all-around FET (GAA-FET). That is, the composition is preferably used in a manufacturing process of the GAA-FET.

The GAA-FET refers to an FET having a structure in which a side surface portion of a channel between a drain and a source is covered with a gate over the entire circumference. Examples of the channel in the GAA-FET include an aspect in which the channel is composed of a nano-sized wire-like member. In the manufacturing of the GAA-FET, for example, a process of selectively removing Si from an object to be treated having a nanostructure is included, and the present composition can be preferably used in such a process.

### <Method for Treating Object to be Treated>

Hereinafter, a method for treating an object to be treated containing SiGe and Si (object to be treated) using the present composition will be described.

### [Object to be Treated]

The object to be treated contains SiGe and Si.

The object to be treated is not particularly limited as long as it contains SiGe and Si, but SiGe and Si are usually disposed on a substrate.

Here, the expression “on a substrate” includes any aspect of front and back surfaces, side surfaces, and inside of grooves of the substrate.

In addition, the aspect of “SiGe and Si are disposed on a substrate” includes a case where SiGe and Si are directly present on the surface of the substrate and a case where SiGe and Si are present on the substrate through another layer.

In addition, in the aspect of “SiGe and Si are disposed on a substrate”, the form of existence of SiGe and Si does not matter as long as SiGe and Si exist on the substrate at the same time. For example, SiGe and Si may be in contact with each other or may be in contact with each other through another layer or member. In addition, there may be a form in which SiGe and Si are not in contact with each other, although SiGe and Si are present on the same substrate.

Examples of the substrate include a metal substrate, a semiconductor substrate, a conductive substrate other than a metal, a metal oxide substrate, a glass substrate, and a resin substrate. Above all, a semiconductor substrate is preferable.

Examples of the semiconductor substrate include a semiconductor wafer, a glass substrate for a photo mask, a glass substrate for liquid crystal display, a glass substrate for plasma display, a substrate for a field emission display (FED), a substrate for an optical disk, a substrate for a magnetic disk, and a substrate for a magneto-optical disk.

Examples of the material constituting the semiconductor substrate include silicon, a Group III-V compound such as GaAs, and a combination thereof.

Examples of the use of the object to be treated include a dynamic random access memory (DRAM), a ferroelectric random access memory (FRAM) (registered trademark), a magnetoresistive random access memory (MRAM), a phase change random access memory (PRAM), a logic circuit, and a processor.

The form of Si or SiGe on the substrate may be any form of film-like arrangement, wiring line-like arrangement, plate-like arrangement, column-like arrangement, and particle-like arrangement.

The object to be treated may include a layer and/or a structure as desired, in addition to SiGe and Si.

For example, one or more members selected from the group consisting of a metal wire, a gate electrode, a source electrode, a drain electrode, an insulating layer, a ferromagnetic layer, and a non-magnetic layer may be disposed on the substrate.

The substrate may include an exposed integrated circuit structure.

Examples of the integrated circuit structure include an interconnection mechanism such as a metal wire or a dielectric material. Examples of metals and alloys used for the interconnection mechanism include aluminum, a copper-aluminum alloy, copper, nickel, nickel silicide, cobalt, cobalt silicide, ruthenium, platinum, gold, titanium, tantalum, tungsten, titanium nitride, and tantalum nitride. The substrate may include one or more layers of materials selected from the group consisting of silicon oxide, silicon nitride, silicon carbide, and carbon-doped silicon oxide.

### [Treatment Method]

The method for treating an object to be treated according to the embodiment of the present invention (hereinafter, also referred to as “the present treatment method”) includes a step A of bringing the above-mentioned composition into contact with an object to be treated containing SiGe and Si. Si in the object to be treated is selectively removed or etched by carrying out the present treatment method.

The object to be treated used in the present treatment method is as described above.

The step A may be one of the steps included in the method for manufacturing a semiconductor element. That is, in the method for manufacturing a semiconductor element, the step A of bringing the above-mentioned composition into contact with an object to be treated containing SiGe and Si may be carried out.

Examples of the method of bringing the composition into contact with the object to be treated include a method of immersing the object to be treated in the composition placed in a tank, a method of spraying the composition onto the object to be treated, a method of pouring the composition onto the object to be treated, and a combination thereof, among which a method of immersing the object to be treated in the composition is preferable.

In order to further increase the treatment rate by the composition, a mechanical stirring method may be used in the step A.

Examples of the mechanical stirring method include a method of circulating the composition on the object to be treated, a method of pouring or spraying the composition on the object to be treated, and a method of stirring the composition by ultrasonic or megasonic waves.

The treatment time of the step A can be appropriately adjusted.

The treatment time (contact time between the composition and the object to be treated) is preferably 0.25 to 10 minutes and more preferably 0.5 to 2 minutes.

The temperature of the composition during the treatment is preferably 20° C. to 100° C. and more preferably 40° C. to 80° C.

### (Other Steps)

The present treatment method and the method for manufacturing a semiconductor element may include other steps in addition to the step A.

Examples of the other steps include a step of forming each of one or more structures selected from the group consisting of a metal wire, a gate structure, a source structure, a drain structure, an insulating layer, a ferromagnetic layer, a non-magnetic layer, and the like (for example, layer formation, etching, chemical mechanical polishing, and modification), a step of forming a resist, an exposure step, a removing step, a heat treatment step, a washing step, and an inspection step.

The present treatment method may be carried out at any stage of a back end process (BEOL: back end of the line), a middle process (MOL: middle of the line), or a front end process (FEOL: front end of the line), and is preferably carried out in a front end process or a middle process.

The present treatment method can also be used in a step for manufacturing a semiconductor element and can be used for treating, for example, a material composed of silicon, an insulating film, a resist film, an anti-reflection film, an etching residue, and an ashing residue, which are present on a substrate. The present treatment method may be used for treating a substrate after chemical mechanical polishing.

### EXAMPLES

Hereinafter, the present invention will be described in more detail with reference to Examples.

The materials, the amounts and proportions of the materials used, the details of treatments, the procedure of treatments, and the like shown in the following Examples can be appropriately modified as long as the gist of the present invention is maintained. Accordingly, the scope of the present invention should not be construed as being limited to the Examples described below.

### <Preparation of Composition>

A mixed solution was obtained by mixing ultrapure water and each component so that the content of each component was as shown in Table 1 which will be described later, and then the mixed solution was sufficiently stirred with a stirrer to prepare compositions of Examples 1 to 23 and Comparative Example 1, respectively. The content of the composition in Table 1 is based on mass, and the remainder of the total of each component is water.

Hereinafter, each component used in the preparation of the composition will be shown.

### [Specific Compound]

Compounds S-1 to S-7 shown in the table below were used as the specific compound. Compound C-1 shown in the table below is a comparative compound not included in the specific compound.

| No. | Compound name | Structural formula |
|---|---|---|
| S-1 | (Ethylenedithio)diacetic acid | 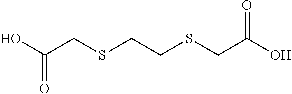 [SMILES: O=C(O)CSCCSCC(=O)O] |
| S-2 | 4,4′-Dithiodimorpholine | 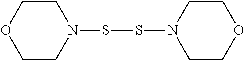 [SMILES: C1CN(SSN2CCOCC2)CCO1] |
| S-3 | L(−)-cystine | 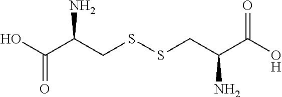 [SMILES: N[C@@H](CSSC[C@H](N)C(=O)O)C(=O)O] |
| S-4 | 3,3′-Dithiodipropionic acid | 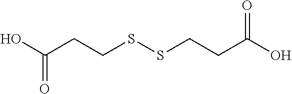 [SMILES: O=C(O)CCSSCCC(=O)O] |
| S-5 | Bis(2-hydroxyethyl)disulfide | 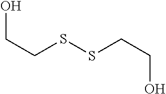 |
| S-6 | 3,3′-Dithiobis(propane-1,2-diol) | 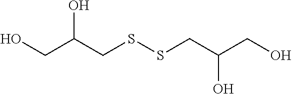 [SMILES: OCC(O)CSSCC(O)CO] |
| S-7 | 4,4′-Disulfanediyl dibenzoic acid | 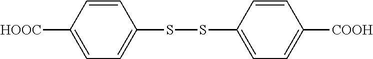 [SMILES: O=C(O)c1ccc(SSc2ccc(C(=O)O)cc2)cc1] |
| C-1 | Suberic acid | 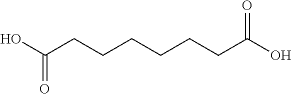 [SMILES: O=C(O)CCCCCCC(=O)O] |

### [Organic Solvent

MEA: monoethanolamine (SP value: 31.1 MIPa^{1/2})
DMSO: dimethyl sulfoxide (SP value: 26.7 MIPa^{1/2})
EG: ethylene glycol (SP value: 33.0 MPa^{1/2})
HG: 2-methylpentane-2,4-diol (SP value: 23.4 MPa^{1/2})
Glycerin (SP value: 35.5 MVPa^{1/2})

### (Quaternary Ammonium Salt)

TMAHI: tetramethyl ammonium hydroxide
TMAF: tetramethyl ammonium fluoride
ETMAH: ethyltrimethyl ammonium hydroxide
TBAH: tetrabutyl ammonium hydroxide

### [Water]

Ultrapure water

### <Evaluation>

The evaluation of the etching rate of SiGe (ER (SiGe)) (that is, SiGe anticorrosion properties) and the ratio of the etching rate of Si to the etching rate of SiGe (ERR (Si/SiGe)) (that is, Si selective removal properties) exhibited by each composition was carried out according to the following procedure.

A SiGe layer (mass ratio: Si/Ge=4/1) was formed on a commercially available 12-inch silicon wafer by heteroepitaxy, and a chip cut into a 2 cm square from the wafer was obtained as a test piece. The thickness of the SiGe layer on the obtained test piece was measured using a spectroscopic ellipsometer (“Vase”, manufactured by J.A. Woollam Japan, Co., Inc.). The test piece was placed in a container filled with the composition of each of Examples or Comparative Examples, and the composition was stirred to carry out an etching treatment for 20 minutes. The temperature of the composition was 45° C.

After the etching treatment, the test piece was washed with water and then dried by nitrogen blowing, and the thickness of the SiGe layer was measured with a spectroscopic ellipsometer. ER (SiGe) (Å/min) was calculated from the change in the thickness of the SiGe layer before and after the etching treatment.

In addition, the same test as described above was carried out on a test piece obtained by forming a Si layer on a SiGe wafer by heteroepitaxy, and the etching rate of Si (ER (Si)) (Å/min) was calculated from the change in the thickness of the Si layer before and after the etching treatment. From the obtained calculation results, the ratio of ER (SiGe) to ER (Si) was calculated to obtain ERR (Si/SiGe).

The ER (SiGe) and the ERR (Si/SiGe) obtained by the above-mentioned measurement were evaluated according to the following evaluation standards.

It is noted that the smaller the value of ER (SiGe), the more preferable it is, and the evaluation of a grade C or higher is preferable in terms of practical use. In addition, the larger the value of ERR (Si/SiGe), the more preferable it is, and the evaluation of a grade C or higher is preferable in terms of practical use.

### [Evaluation Standards for ER (SiGe)]

A: less than 10 Å/min
B: 10 Å/min or more and less than 25 Å/min
C: 25 Å/min or more and less than 40 Å/min
D: 40 Å/min or more

### [Evaluation Standards for ERR (Si/SiGe)]

A: 25 or more
B: 15 or more and less than 25
C: 5 or more and less than 15
D: less than 5

### <Results>

The formulation of the composition and the evaluation results are shown in Table 1.

In the table, “Content” of each component represents the content (% by mass) of each component with respect to the total mass of the composition. In each composition, the remainder of the total content of each component is water.

“pH” in the table indicates a value displayed in a case where the pH of the composition is measured using a pH meter (F-71S (trade name), manufactured by Horiba, Ltd.). The measurement temperature was 25° C.

TABLE 1

| | Composition | | | | | | | | |
|---|---|---|---|---|---|---|---|---|---|
| | Specific | | | | | | | | |
| | compound or | | | | | | | | |
| | comparative | | | | Quaternary | | | | |
| | compound | | Organic solvent | | ammonium salt | | | | |
| | | Content | | Content | | Content | | Evaluation | |
| | | (% by | | (% by | | (% by | | ER | ERR |
| | Type | mass) | Type | mass) | Type | mass) | pH | (SiGe) | (Si/SiGe) |
| Example 1 | S-1 | 1.0 | MEA | 50 | TMAH | 2.0 | 14.1 | C | C |
| Example 2 | S-2 | 0.1 | DMSO | 50 | TMAH | 2.0 | 13.9 | B | C |
| Example 3 | S-3 | 1.0 | MEA | 50 | TMAH | 2.0 | 14.0 | B | B |
| Example 4 | S-4 | 1.0 | MEA | 50 | TMAH | 2.0 | 14.1 | A | B |
| Example 5 | S-5 | 1.0 | MEA | 50 | TMAH | 2.0 | 14.1 | A | C |
| Example 6 | S-6 | 1.0 | MEA | 50 | TMAH | 2.0 | 14.4 | A | A |
| Example 7 | S-6 | 0.1 | MEA | 50 | TMAH | 2.0 | 14.4 | A | A |
| Example 8 | S-6 | 0.01 | MEA | 50 | TMAH | 2.0 | 14.4 | B | A |
| Example 9 | S-6 | 2.0 | MEA | 50 | TMAH | 2.0 | 14.4 | A | A |
| Example 10 | S-6 | 5.0 | MEA | 50 | TMAH | 2.0 | 14.4 | A | B |
| Example 11 | S-6 | 1.0 | MEA | 50 | TMAF | 1.0 | 13.8 | B | A |
| Example 12 | S-6 | 1.0 | DMSO | 50 | TMAH | 2.0 | 14.2 | A | B |
| Example 13 | S-7 | 1.0 | MEA | 50 | TMAH | 2.0 | 14.4 | A | A |
| Example 14 | S-7 | 1.0 | EG | 50 | TMAH | 2.0 | 14.2 | A | A |
| Example 15 | S-7 | 1.0 | HG | 50 | TMAH | 2.0 | 14.2 | A | A |
| Example 16 | S-7 | 1.0 | Glycerin | 50 | TMAH | 2.0 | 14.2 | A | A |
| Example 17 | S-7 | 1.0 | MEA | 50 | — | — | 13.1 | A | B |
| Example 18 | S-7 | 1.0 | MEA | 30 | TMAH | 2.0 | 13.4 | B | A |
| Example 19 | S-6 | 0.5 | MEA | 50 | TMAH | 2.0 | 14.4 | A | A |
| | S-7 | 0.5 | | | | | | | |
| Example 20 | S-7 | 1.0 | MEA | 25 | TMAH | 2.0 | 14.3 | A | A |
| | | | EG | 25 | | | | | |
| Example 21 | S-6 | 1.0 | MEA | 50 | ETMAH | 2.3 | 14.4 | A | A |
| Example 22 | S-6 | 1.0 | MEA | 50 | TBAH | 2.8 | 14.4 | A | A |
| Example 23 | S-6 | 1.0 | MEA | 50 | TMAH | 1.0 | 14.4 | A | A |
| | | | | | ETMAH | 2.3 | | | |
| Comparative | C-1 | 0.1 | MEA | 50 | TMAH | 2.0 | 14.1 | D | D |
| Example 1 | | | | | | | | | |

From the results in Table 1, it was confirmed that the composition for manufacturing a semiconductor according to the embodiment of the present invention, which contains the specific compound, was more excellent in Si selective removal properties than the composition for manufacturing a semiconductor of Comparative Example 1, which does not contain the specific compound.

It was confirmed that, in a case where the specific compound had a disulfide group, at least one of Si selective removal properties or SiGe anticorrosion properties was more excellent (comparison of Example 1 with Examples 2 to 6 and 13).

It was confirmed that, in a case where the specific compound had a disulfide group and at least one group selected from the group consisting of an amino group, a hydroxy group, and a carboxy group, at least one of Si selective removal properties or SiGe anticorrosion properties was more excellent (comparison of Example 2 with Examples 3 to 6 and 13).

It was confirmed that, in a case where the specific compound had 3 or more hydroxy groups, the Si selective removal properties were more excellent than those in a case where the specific compound had 2 hydroxy groups (comparison of Example 5 with Example 6).

It was confirmed that, in a case where the content of the specific compound was 2.0% by mass or less with respect to the total mass of the composition for manufacturing a semiconductor, the Si selective removal properties were more excellent (comparison of Example 10 with Examples 6 to 9). In addition, it was confirmed that, in a case where the content of the specific compound was 0.1% by mass or more with respect to the total mass of the composition for manufacturing a semiconductor, the SiGe anticorrosion properties were more excellent (comparison of Example 8 with Examples 6, 7, 9, and 10).

It was confirmed that, in a case where the organic solvent had at least one of a hydroxy group or an amino group, the SiGe anticorrosion properties were more excellent than those in a case where the organic solvent had neither a hydroxy group nor an amino group (comparison of Example 6 with Example 12, and comparison of Examples 13 to 16).

It was confirmed that, in a case where the content of the organic solvent was 40% by mass or more with respect to the total mass of the composition for manufacturing a semiconductor, the SiGe anticorrosion properties were more excellent (comparison of Example 13 with Example 18).

It was confirmed that, in a case where the composition for manufacturing a semiconductor contained a quaternary ammonium salt, the Si selective removal properties were more excellent than those in a case where the composition for manufacturing a semiconductor did not contain a quaternary ammonium salt (comparison of Example 13 with Example 17).

It was confirmed that, in a case where the composition for manufacturing a semiconductor contained a quaternary ammonium hydroxide, the SiGe anticorrosion properties were more excellent than those in a case where the composition for manufacturing a semiconductor contained a quaternary ammonium salt other than the quaternary ammonium hydroxide (comparison of Example 6 with Examples 11 and 21 to 23).

What is claimed is:

1. A composition for manufacturing a semiconductor, comprising:
a specific compound having two or more sulfur atoms and one or more heteroatoms other than a sulfur atom;
an organic solvent; and
water,
wherein the composition is alkaline.

2. The composition for manufacturing a semiconductor according to claim 1,
wherein the specific compound has a disulfide group.

3. The composition for manufacturing a semiconductor according to claim 1,
wherein the specific compound has at least one group selected from the group consisting of an amino group, a hydroxy group, a carbonyl group, and a carboxy group.

4. The composition for manufacturing a semiconductor according to claim 1,
wherein the specific compound has 3 or more hydroxy groups.

5. The composition for manufacturing a semiconductor according to claim 1,
wherein the specific compound has an aromatic hydrocarbon group substituted with a polar group containing a heteroatom other than a sulfur atom.

6. The composition for manufacturing a semiconductor according to claim 1,
wherein the specific compound has a disulfide group and at least one group selected from the group consisting of an amino group, a hydroxy group, a carbonyl group, and a carboxy group.

7. The composition for manufacturing a semiconductor according to claim 1,
wherein the specific compound has a disulfide group and three or more hydroxy groups.

8. The composition for manufacturing a semiconductor according to claim 1,
wherein the specific compound has a disulfide group, and an aromatic hydrocarbon group substituted with a polar group containing a heteroatom other than a sulfur atom.

9. The composition for manufacturing a semiconductor according to claim 1,
wherein the composition for manufacturing a semiconductor further comprises a quaternary ammonium salt.

10. The composition for manufacturing a semiconductor according to claim 9,
wherein the quaternary ammonium salt is a quaternary ammonium hydroxide.

11. The composition for manufacturing a semiconductor according to claim 1,
wherein the organic solvent has at least one of a hydroxy group or an amino group.

12. The composition for manufacturing a semiconductor according to claim 1,
wherein a content of the organic solvent is 40% by mass or more with respect to a total mass of the composition for manufacturing a semiconductor.

13. The composition for manufacturing a semiconductor according to claim 1,
wherein the composition is used for an object to be treated containing silicon-germanium and silicon.

14. The composition for manufacturing a semiconductor according to claim 1,
wherein the composition has a pH of 11 or more.

15. A method for treating an object to be treated, comprising:
bringing an object to be treated containing silicon-germanium and silicon into contact with the composition for manufacturing a semiconductor according to claim 1 to remove silicon.

16. A method for manufacturing a semiconductor element, comprising:
a step of bringing an object to be treated containing silicon-germanium and silicon into contact with the composition for manufacturing a semiconductor according to claim 1 to remove silicon.

17. The composition for manufacturing a semiconductor according to claim 2,
wherein the specific compound has at least one group selected from the group consisting of an amino group, a hydroxy group, a carbonyl group, and a carboxy group.

18. The composition for manufacturing a semiconductor according to claim 2,
wherein the specific compound has 3 or more hydroxy groups.

19. The composition for manufacturing a semiconductor according to claim 2,
wherein the specific compound has an aromatic hydrocarbon group substituted with a polar group containing a heteroatom other than a sulfur atom.

20. The composition for manufacturing a semiconductor according to claim 2,
wherein the specific compound has a disulfide group and at least one group selected from the group consisting of an amino group, a hydroxy group, a carbonyl group, and a carboxy group.
